(19) United States
(12) Patent Application Publication
(10) Pub. No.: US 2007/0074087 A1
(43) Pub. Date: Mar. 29, 2007

(54) System and method for writing information to an optical medium with predicting of defect characteristics

(76) Inventor: Hong-Jing Lo, Austin, TX (US)

Correspondence Address: HAMILTON & TERRILE, LLP, P.O. BOX 203518, AUSTIN, TX, 78720, US

(21) Appl. No.: 11/236,350

(22) Filed: Sep. 27, 2005

(51) Int. Cl. G11C 29/00

(52) U.S. Cl. 714/710

(57) ABSTRACT

An optical drive provides more rapid writes to an optical medium by analyzing defects detected on the optical medium to predict defect areas and avoid writes to the predicted defect areas until the defects are confirmed or refuted. For instance, a defect detector analyzes for a predicted defect if two or more substantially adjacent blocks of the optical medium are determined as defective by associating the determined defectives with a defect shape, such as a scratch, a fingerprint or a spot. The predicted defect is an area of the optical medium extended in the form of the shape in the direction of subsequent writes. The predicted defects are confirmed or refuted with test writes during an idle time, such as after completion of the write or in batches that make updates to a defect table more efficient.

### BACKGROUND OF THE INVENTION

1. Field of the Invention

The present invention relates in general to the field of storing information with an information handling system on an optical medium, and more particularly to a system and method writing information to an optical medium with predicting of defect characteristics.

2. Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

As information handling systems have grown more powerful over time, users have generated increased amounts of information for storage. One difficulty associated with this increased amount of information is the storage of larger-sized files on portable storage mediums. Optical media have become a popular alternative for storing information on a portable medium due to relatively small cost, convenience and available storage. For example, a conventional CD optical medium stores approximately 700 MB of information, a conventional DVD optical medium stores approximately 4 GB of information and newly developed Blu-Ray optical medium will store approximately 20 GB of information. Further, optical media are available in re-writable formats so that a user can write on the same medium multiple times much like a conventional magnetic floppy disc. To take advantage of these similarities and the familiarity that users have with magnetic floppy discs, industry has attempted to mimic the use of magnetic floppy discs in the storage of information on optical media. For instance, to ensure the integrity of information stored on optical media, defect tables are enabled on the optical media that are similar to the defect tables used by hard drives.

One problem that arises with the use of optical media for storing information is that imperfections on the recording surface of the optical media may cause defects in the writing of information to the optical media. For instance, some examples of defects include scratches, fingerprints or other marks caused by contact of external sources against the surface. These types of defects can cause erroneous reading and writing of information because the laser of the optical drive cannot reach the data layer of an optical medium as intended. Further, if a substantial number of the defects have not been allocated to the defect table on the optical medium, significant performance degradation can occur when reading from and writing to the optical medium. The performance degradation occurs because the optical drive will attempt to reallocate information from potentially defective areas while updating the defect tables. Latency occurs as the drive repeatedly moves its pickup unit to the defect table and back to the area where of the optical medium where information is being read or written. Since this movement is performed for each defective block of the optical medium, the amount of latency increases as the amount of newly located defects increases.

### SUMMARY OF THE INVENTION

Therefore a need has arisen for a system and method which more effectively manages defects associated with an optical medium.

In accordance with the present invention, a system and method are provided which substantially reduce the disadvantages and problems associated with previous methods and systems for managing defects associated with an optical medium. Areas of the optical medium predicted to have defects are avoided for writing information to the optical medium. Avoiding predicted defective areas during information writes reduces the number and frequency of defect table updates and allows testing to confirm or refute predicted defects during periods that do not interfere with information writes.

More specifically, an optical drive has a defect detector that detects defects in information written to an optical medium and maintains a defect table of defective areas on the optical drive. A defect predictor analyzes the detected defects to predict areas of the optical medium likely to have defects and directs the drive to avoid writes of information to the predicted defective areas. For instance, the defect predictor associates substantially adjacent detected defects with one of plural defect types, such as a scratch, a fingerprint or a spot, and extends the shape and size of the defect to predict areas in subsequent information writes that are likely to have a defect. By avoiding writes to these predicted defective areas, the defect predictor reduces the number and frequency of defects detected by the defect detector and thus reduces delays to information writes by intermediate updates to the defect table. A defect confirmer writes test information during idle times, such as after the information write is complete, to confirm or refute the predicted defect areas and update the defect table.

The present invention provides a number of important technical advantages. One example of an important technical advantage is that predicting a defect's size and shape allows an optical drive to avoid write attempts to areas of the optical medium that are likely defective. By reference to the predicted defect area, the optical drive makes fewer entries to the defect table during a given write operation and thus performs the write operation more quickly. Confirming the status of blocks within the optical medium that are predicted as defective during idle or non-writing periods avoids incorrect categorizing of non-defective areas as defective without impacting write operations.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 depicts a block diagram of an information handling system configured to predict defective areas of an optical medium;

FIG. 2 depicts an example of predicted defective areas for a radial scratch defect; and

FIG. 3 depicts flow diagram-of an example of a process for predicting defective areas of an optical medium.

### DETAILED DESCRIPTION

Predicting defective areas of an optical medium provides more efficient writes of information from an information handling system by reducing the number and frequency of writes made by an optical drive to a defect table on the optical medium. For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

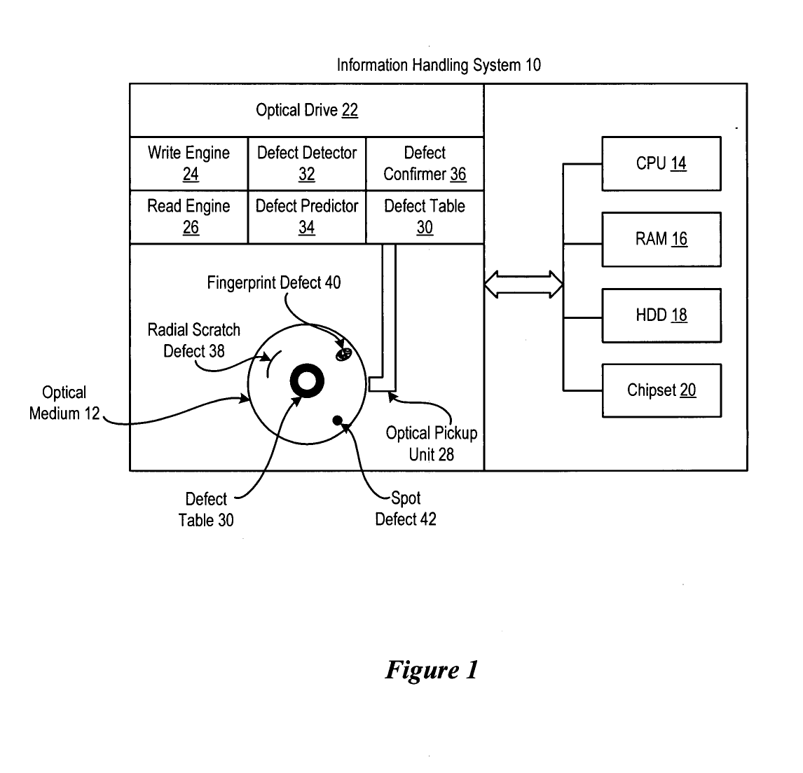

Referring now to FIG. 1, a block diagram depicts an information handling 10 system configured to predict defective areas of an optical medium 12. Optical medium 12 is, for instance, a CD, DVD or BD medium that accepts information writes with an IR, red or blue laser respectively. Information handling system 10 is built from plural processing components, such as a CPU 14, RAM 16, a hard disk drive 18 and chipset 20, which cooperate to process information. For example information generated by the processing components may be communicated to an optical drive 22 for writing to optical medium 12. A write engine 24 coordinates information writes to optical medium 12 and a read engine 26 coordinates information reads from optical medium 12, such as with firmware instructions running on a microprocessor within optical drive 22. Writes to optical medium 12 are performed through an optical pickup unit 28 having lasers to illuminate optical medium 12 with sufficient power to alter the reflective characteristics of the optical medium's material. Reads from optical medium 12 are performed with less powerful illumination so that reflections from the optical medium are received and measured at optical pickup unit 28.

During a write of information to optical medium 12, a check is made to a defect table 30 to ensure that the write is not made to an area having a defect that will cause a failure of the write. For instance, defect table 30 lists addresses of blocks on optical medium 12 that have defects that prevent an accurate write of information. In addition, a defect detector 32 checks writes that are made and identifies inaccurate writes as defect areas that are added to defect table 30. For instance, after a write to a block is complete, defect detector 32 reads the information from the optical medium to ensure that it matches the information written. A failure of the read information to match what was written results in the block's identification as a defect area in defect table 30 and write of the information to a different block. However, the movement of optical pickup unit 28 to defect table 30 to add the defective area to the table reduces the speed at which the write occurs since the optical pickup unit is interrupted from its primary task of writing information in order to write to the defect table. The impact of writes to defect table 30 is magnified since the defect table is typically located at the inner diameter of optical medium 12 so that optical pickup unit 28 has to move some distance between where information is written and the inner diameter at each defect table update.

In order to minimize the impact of defect table updates on write speeds, a defect predictor 34 predicts if an area is defective and has write engine 24 avoid writes of information to the predicted defective areas. By avoiding writes to predicted defective areas, defect predictor 34 reduces the frequency of writes to defective areas and thus reduces the frequency of updates to defect table 30. To reduce the waste of space on optical medium 12 due to excessive determinations of predicted defects, a defect confirmer 36 periodically commands test writes to predicted defective areas to confirm or refute that the areas are defective. For instance, defect confirmer 36 performs test writes after the write of information to optical medium 12 is complete so that confirmation of defects does not interfere with and slow writes of information to optical medium 12. If test writes done during an idle period confirm that a predicted defect area is defective, then the update to defect table 30 does not interfere with other optical drive operations. Further, defect confirmer 36 can perform test writes in batches of predicted defective areas to have fewer batch updates to defect table 30.

Defect predictor 34 predicts areas likely to have defects by analyzing detected defect areas from defect table 30 or as defect detector 32 detects new defects. For example, defect predictor 34 analyzes substantially adjacent defect areas to determine if these areas fall into one of plural types of defect patterns. If a defect pattern is likely, defect predictor 34 estimates the size and shape of the defect pattern and extends the size and shape a predetermined number of blocks of optical medium 12 in the direction in which subsequent writes will be made. These predetermined number of blocks are predicted defective areas which defect predictor 34 has write engine 24 skip over in writing information to optical medium 12 to write information instead to subsequent blocks. Some examples of defect patterns analyzed by defect predictor 32 include a radial scratch defect 38, a fingerprint defect 40 and a spot defect 42 having a substantially symmetrical shape, such as a circle. In alternative embodiments, alternative predicted shapes and models to identify the predicted shapes may be used.

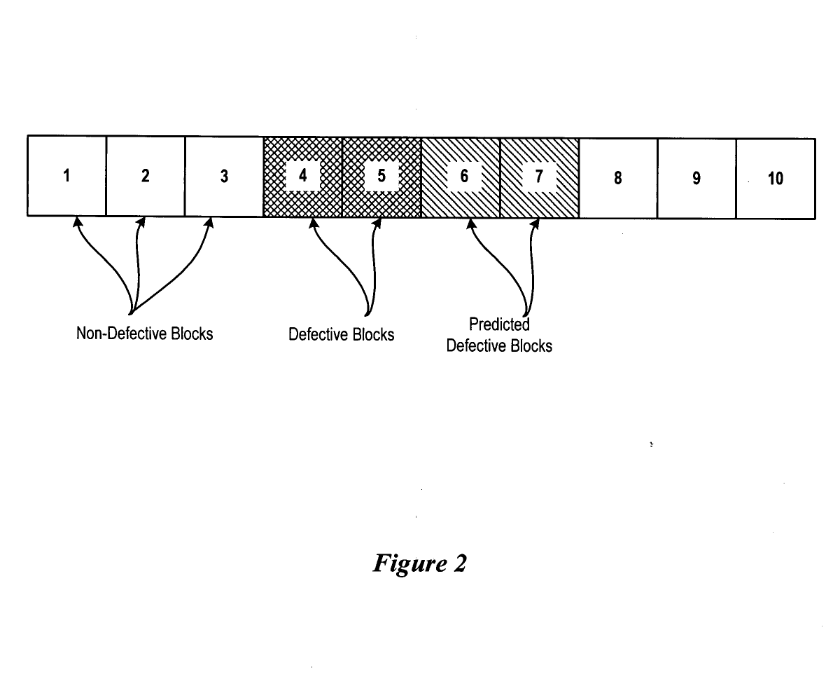

Referring now to FIG. 2, an example of predicted defective areas for a radial scratch defect is depicted. As depicted in FIG. 1, radial scratch defect 38 falls along the path of optical pickup unit 28 as optical medium 12 rotates relative to optical pickup unit 28. The first three blocks in FIG. 2 are successfully written with information, however, the radial defect begins at block 4. Defect detector 32 detects the defect of the attempt to write block 4 and block 5 and adds blocks 4 and 5 to defect table 30. Defect predictor 34 analyzes the adjacent defects at blocks 4 and 5 to predict a radial scratch defect and therefore predicts that the next two blocks, blocks 6 and 7, are likely to also have defects. Defect predictor 34 directs write engine 24 to avoid writes to blocks 6 and 7, the predicted defective areas, and instead skip to block 8 to attempt a write. The process of predicting defects based on the analyzed radial scratch continues until a nondefective block is detected, and then writes of information continue until defect detector 34 detects additional defect patterns.

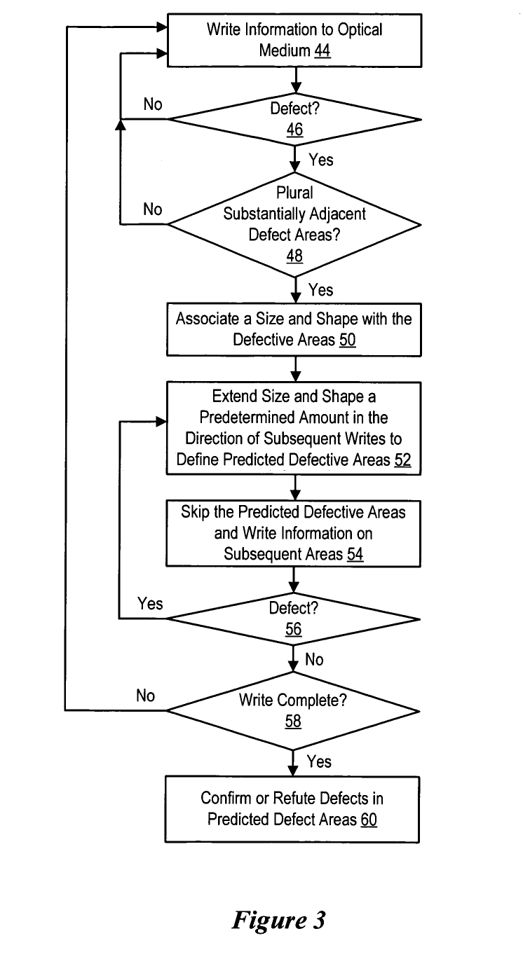

Referring now to FIG. 3, a flow diagram depicts an example of a process for predicting defective areas of an optical medium. The process begins at step 44 with writes of information to an optical medium. At step 46, if no defects are detected the process returns to step 44 to continue to write the information. If at step 46 a defect is detected, the process continues to step 48 to determine if plural substantially adjacent defective areas are found. If not, a defect shape is not found and the process returns to step 44. If plural substantially adjacent defective areas are determined, the process continues to step 50 to associate a size and shape with the defective areas. At step 52, the predicted size and shape of the defective area is extended a predetermined amount in the direction of subsequent writes to define predicted defective areas. At step 54, the predicted defective areas are skipped over and a write of information is made on a subsequent area of the optical medium. If at step 56 the write on the subsequent area has a defect, the process returns to step 52 to further extend the size and shape of the defective area. If at step 56 the write on the subsequent area does not have a defect, the process continues to step 58 to determine if the write is complete. If the write is not complete, the process returns to step 44 to continue with the write. If the write is complete, at step 60 the predicted defective areas are tested to confirm or refute that a defect exists and the defect table is updated as appropriate.

Although the present invention has been described in detail, it should be understood that various changes, substitutions and alterations can be made hereto without departing from the spirit and scope of the invention as defined by the appended claims.

What is claimed is:

1. A method for managing defects of an optical medium, the method comprising:
detecting one or more defect areas on the optical medium;
analyzing the one or more detected defect areas to predict one or more predicted defect areas on the optical medium;
writing information to the optical medium; and
avoiding the predicted defect areas during the writing of information to the optical medium.

2. The method of claim 1 further comprising:
completing the writing of information; and
testing the predicted defect areas to determine if a defect exists.

3. The method of claim 2 further comprising updating a defect table on the optical medium if a predicted defect area is determined to have a defect.

4. The method of claim 3 wherein the predicted defect area comprises one or more blocks.

5. The method of claim 1 wherein analyzing further comprises:
determining that the detected defect areas have a predetermined shape formed in a direction;
extending the predetermined shape in the direction by a predetermined distance; and
predicting that the areas extending in the direction by the predetermined distance is defective.

6. The method of claim 5 wherein avoiding the predicted defect areas further comprises initiating writing to the optical medium at the area beyond the predetermined distance.

7. The method of claim 5 wherein the predetermined shape comprises a scratch.

8. The method of claim 5 wherein the predetermined shape comprises a fingerprint.

9. The method of claim 5 wherein the predetermined shape comprises a substantially symmetric spot.

10. A system for managing defects of an optical medium, the system comprising:
a defect detector operable to determine defect areas of the optical medium by identifying areas of the optical medium that fail to correctly record information; and
a defect predictor operable to analyze determined defect areas to predict areas of the optical medium that have defects.

11. The system of claim 10 further comprising:
a write engine interfaced with the defect predictor and operable to write information to the optical medium, the write engine avoiding writes of the information to the areas of the optical medium predicted to have defects.

12. The system of claim 11 further comprising:
a defect confirmer interfaced with the write engine and operable to command selective test writes to areas of the optical medium predicted to have defects to confirm or refute that the areas predicted to have defects do have defects.

13. The system of claim 12 further comprising:
a defect table stored on the optical medium, the defect detector and the detect confirmer operable to add defect areas to the defect table.

14. The system of claim 10 where in the defect predictor analyzes determined defect areas by associating plural defects with one of plural predetermined shapes.

15. The system of claim 14 wherein the predetermined shape comprises a scratch.

16. The system of claim 14 wherein the predetermined shape comprises a fingerprint.

17. The system of claim 14 wherein the predetermined shape comprises a spot.

18. An information handling system comprising:
plural processing components operable to process information for writing to an optical medium;
an optical drive interfaced with the processing components and operable to write the information to the optical medium and to read information from the optical medium;
a defect determiner associated with the optical drive, the defect determiner operable to determine defective areas of the optical medium and to record the defective areas in a defect table stored on the optical medium; and
a defect predictor associated with the optical drive, the defect predictor operable to analyze the defective areas to identify predicted defective areas and to restrict writing of the information to the predicted defective areas.

19. The information handling system further comprising:
a defect confirmer associated with the optical drive and operable to test write information to predicted defective areas to confirm or refute the predicted defects.

20. The information handling system of claim 18 wherein the defect predictor is further operable to analyze the defective areas by:
determining that the detected defect areas have a predetermined shape formed in a direction;
extending the predetermined shape in the direction by a predetermined distance; and
predicting that the areas extending in the direction by the predetermined distance is defective.
